(19) United States
(12) Patent Application Publication
(10) Pub. No.: US 2002/0177007 A1
(43) Pub. Date: Nov. 28, 2002

(54) Electroluminescent devices and method of manufacturing the same

(76) Inventors: Boris Chernobrod, Lexington, MA (US); Michael Schwartz, Andover, MA (US); Vladimir Schwartz, Lexington, MA (US)

Correspondence Address: BAKER & MCKENZIE, 805 THIRD AVENUE, NEW YORK, NY, 10022, US

(21) Appl. No.: 09/866,270

(22) Filed: May 25, 2001

(51) Int. Cl. H05B 33/00

(52) U.S. Cl. 428/690; 428/917; 428/201; 428/156; 427/66; 430/311; 313/504; 313/505; 257/88; 257/97

(57) ABSTRACT

An electroluminescent device useful as an optical memory or display. The device includes one or more device layers or elements 100. The device layers each include a substrate 200 with indentations 202, a cathode electrode layer 204 having a transparent conductor sub-layer 206 and an electron emission sub-layer 208, a pit pillar structure layer 210 with pixel pits 212, an n-type light emitting pixel material 214, a p-type light emitting pixel material 216 and anodes 218. The light emitting materials 214, 216 in the pixel pits 212 are deposited by a liquid deposition such as molecular adhesion and electro-polymerized. The pixel pits 212 may have dimensions of less than 10 μm with the smaller pixels having dimensions of less than half a micron.

### FIELD OF THE INVENTION

The present invention generally relates to electroluminescent devices including organic polymer light emissive materials and the processes for producing those devices. More particularly, the present invention relates to electroluminescent optical memories and displays that have small pixels of organic polymer light emissive materials and the processes for producing those devices.

### BACKGROUND

The primary function of optical memory is to store information. Cost and the ever-increasing need for more memory are constantly driving the optical memory industry to find cheaper and more compact ways to store information. The compactness of optical memory is determined by the density of the emissive pixels and is inversely proportional to the light emitting polymer pixel area. Thus, a primary goal of the optical memory industry is to increase the pixel density. This may be achieved by decreasing the pixel area.

The pixel area is primarily limited by the processing steps that pattern the organic polymer materials. Lithographic etch, step and repeat processes, ink-jet printing and other current methods have dimensional limits that allow for pixels size of 18 to 20 μm. The dimensional limit of lithographic etch, step and repeat processes is in part due to the chemical etching limits of the polymer materials. The chemical etching limits make processing so difficult that acceptable yields cannot be achieved. RIE overcomes some of the problems associated with the lithographic etch, step and repeat process but requires millions of dollars of fabrication equipment that is expensive to operate and maintain. Ink jet printing is an inexpensive alternative to RIE and lithographic etch, step and repeat methods, but has the largest dimensional limit. The above dimensional limits necessitate large pixel areas (e.g., greater than 100 μm²).

Accordingly, there is a strong need in the art for a compact optical memory that is inexpensive to manufacture.

### SUMMARY OF THE INVENTION

An aspect of the invention provides for a method of making an electroluminescent element including forming a cathode, forming a layer, forming pixel pits in the layer, depositing light emitting material into the pixel pits by a liquid deposition, and forming an anode such that the anode and the cathode can excite the light emitting material.

Another aspect of the invention provides for an electroluminescent element including a layer including pixel pits, an organic polymer light emitting pixel formed in the pixel pits, a first portion of the organic polymer light emitting pixel being an n-type material and a second portion of the organic polymer light emitting pixel being a p-type material, and an anode and a cathode for applying an excitation to the organic polymer light emitting pixel. The at least one dimension organic polymer light emitting pixel parallel to the layer is equal to or less than about 10 μm.

A further aspect of the invention provides for a method of making an optical memory element including nanoimprinting a substrate, forming an cathode by depositing a transparent conductive material on the substrate and by depositing an electron emission material on the transparent conductive material, forming a layer on the cathode, forming pixel pits in the layer, depositing light emitting material into the pixel pits by a liquid deposition, and forming an anode by depositing a transparent conductive material such that the anode and the cathode can excite the light emitting material. The at least one non-thickness dimension of the pixel pits is between about 0.5 μm and about 1.0 μm.

A still further aspect of the invention provides for an electroluminescent optical memory element including a substrate with nanoimprinted indentations, a layer including pixel pits, an organic polymer light emitting pixel formed in the pixel pits, a first portion of the organic polymer light emitting pixel being an n-type material and a second portion of the organic polymer light emitting pixel being a p-type material, and an indium tin oxide anode and a dual layer cathode for applying an excitation to the organic polymer light emitting pixel, the dual layer cathode including an indium tin oxide sub-layer and an electron emissive sub-layer having a low work function and high carrier concentration. The at least one dimension of the organic polymer light emitting pixel parallel to the layer is between about 0.5 μm and about 1.0 μm.

### BRIEF DESCRIPTION OF THE DRAWINGS

FIG. 1 is a top view of a device layer illustrating the arrangement of pixel pits;

FIG. 2 is a partial top view of a device layer illustrating the relationship of the cathodes, anodes and pixel pits;

FIG. 3 is a side view of a substrate prior to processing;

FIG. 4 is a side view of a substrate after being imprinted with indentations;

FIG. 5 is a side view of a substrate after vapor deposition of a cathode electrode layer;

FIG. 6 is a side view of a partially completed device layer after patterning of the cathode electrode layer;

FIG. 7 is a side view of a partially completed device layer after deposition of a pit pillar structure layer;

FIG. 8 is a side view of a partially completed device layer after forming pixel pits in a pit pillar structure layer;

FIG. 9 is a side view of a partially completed device layer after deposition of the light emitting pixel materials;

FIG. 10 is a side view of a device layer according to an exemplary embodiment; and

FIG. 11 is a side view of a multi-layer laminate according to another exemplary embodiment.

### DETAILED DESCRIPTION

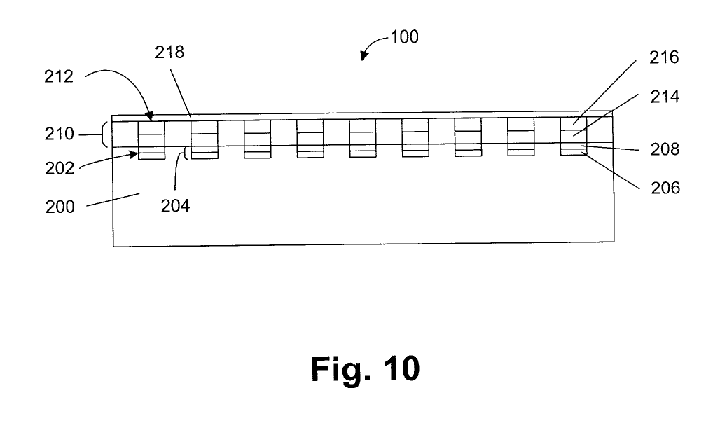

In the drawings, like reference numerals designate like parts. FIG. 10 illustrates a side view of a completed device layer or element 100 according to an exemplary embodiment of the present invention. The completed device layer 100 includes a substrate 200 that provides structural support to the device layer 100. Indentations 202 on a surface of the substrate 200 provide a recess for a cathode electrode layer 204 such that a pit pillar structure layer 210 can be formed on a level surface. The pit pillar structure layer 210 includes pixel pits 212 that define and house the light emitting materials 214, 216. On one side of the pit pillar structure layer 210 is the cathode electrode layer 204 which has a transparent conductor sub-layer 206 to insure the good conductivity of the cathode electrode layer 204 and an electron emission sub-layer 208 to insure there are sufficient majority carriers (electrons) being supplied to a n-type light emitting material 214. The n- and p-type light emitting materials 214, 216 form a pn junction that will emit light (photons) when majority carriers (electrons) from the n-type material 214 recombine with minority carriers (holes) from the p-type light emitting material 216. On the other side of the pit pillar structure layer 210 are the anodes 218 that complete the electric circuit through each pixel pit 212 that enables excitation voltage to be applied. It is this excitation voltage that causes the light emitting materials 214, 216 to generate light. It should be noted that alterations and/or additional elements may be included in the device layer 100 without departing from the spirit or scope of the present invention.

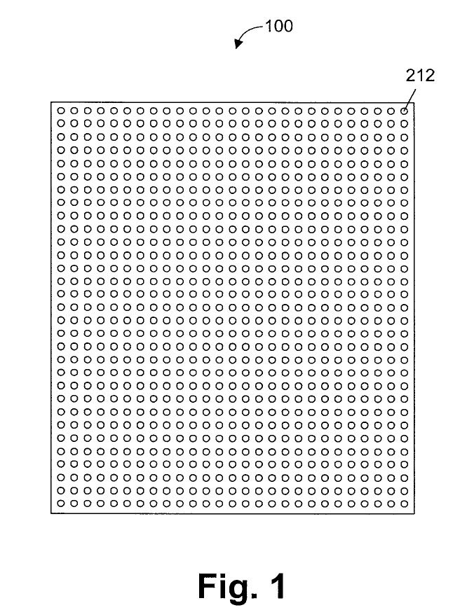

FIG. 1 is a top view of device layer 100 and illustrates the arrangement of the pixel pits 212. The pixel pits 212 are of substantially equal size and arranged in an M×N matrix. The pixel pits 212 are circular or substantially circular with a diameter of less than or equal to 1 μm. Preferably, the pixel pits 212 have a diameter of about 0.5 μm or smaller. Alternatively, the pixel pits 212 may be as large as desired, typically about 5 μm or even 10 μm, or smaller than about 0.5 μm. Preferably the pixel pits 212 have dimensions in the range of about 0.5 to 1.0 μm. Alternatively, the pixel pits 212 can be any regular shape including rectangles, squares, pentagons and the like or may be portions of elongated grooves.

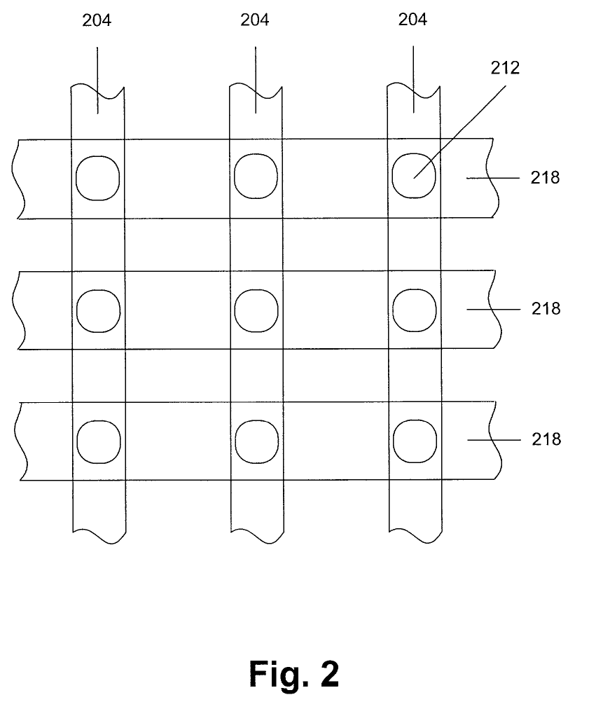

FIG. 2 is a partial top view of a device layer 100 illustrating the relationship of the cathodes 204, anodes 218 and pixel pits 212. In this exemplary embodiment, the cathodes 204 and anodes are striped conductors oriented in orthogonal directions. The pixel pits 212 that contain the light emitting materials 214, 216 are located where the cathodes 204 and anodes 218 overlap one another. An excitation voltage applied to the ends of one of the cathodes 204 and one of the anodes 218 results in the excitation voltage being applied to the light emitting materials 214, 216 in the pixel pit 212 that are sandwiched between that one cathode 204 and that one anode 218. It is also possible to have configurations that are not striped or orthogonal, and that include active elements.

For optical memory devices, the application of the excitation voltage reads whether or not the light emitting materials have been rendered incapable of generating light by attempting to cause a pixel to emit light. The presence or absence of generated light indicates the data point for that pixel. For display devices, the application of voltage to each pixel will display the data encoded in the one or more display layer 100 as a static image such as a sign or the like. The selective application of voltages to one or more display layers 100 can be used to generate variable images such as television images.

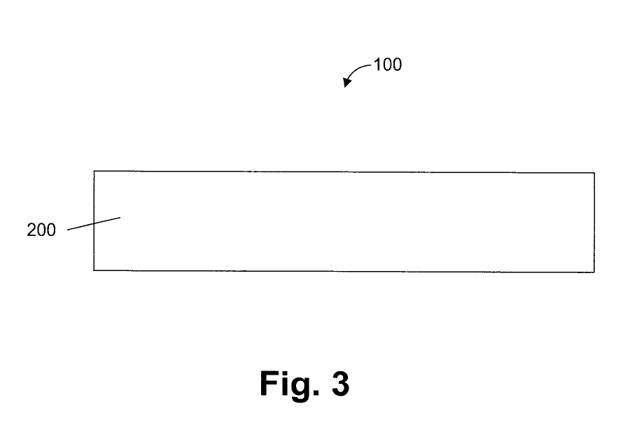

FIG. 3 is a side view of a substrate 200 prior to processing. The substrate 200 may be made from any suitable imprintable substrate material. For example, a 25 μm thick polymethyl methacrylate substrate could be used.

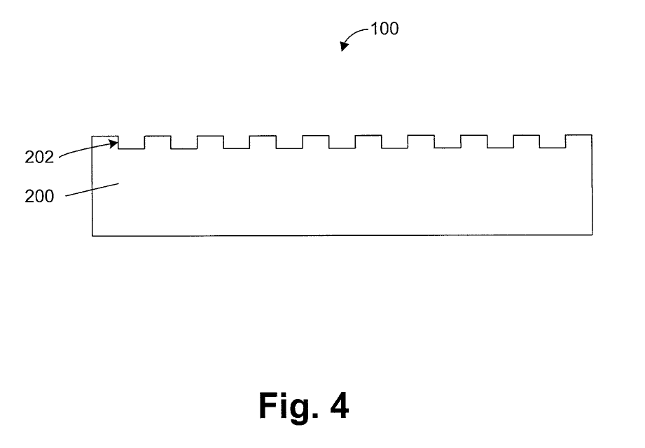

FIG. 4 is a side view of the substrate 200 shown in FIG. 3 after being imprinted with indentations 202. In an exemplary embodiment, the indentations 202 are a few hundred nanometers in depth. The indentations 202 can be formed by nanoimprinting in accordance with the nanoimprinting lithographic method disclosed in U.S. Pat. No. 5,772,905 or by another suitable method such as laser ablation.

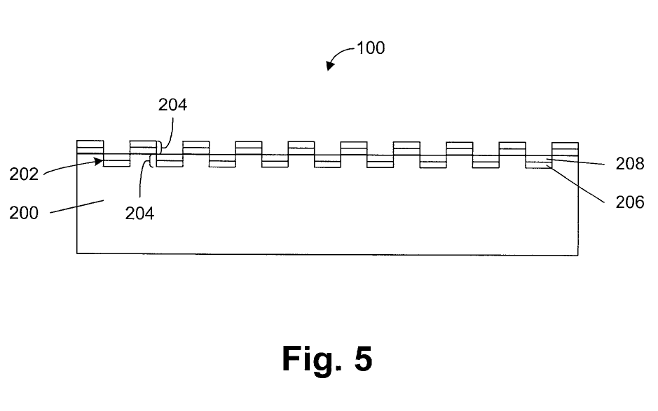

FIG. 5 is a side view of the substrate shown in FIG. 4 after vapor deposition of the cathode electrode layer 204. The cathode electrode layer 204 includes a transparent conductor sub-layer 206 and an electron emission sub-layer 208. The transparent conductive sub-layer 206 can be a transparent conductive oxide such as indium tin oxide or aluminum zinc oxide or any other transparent conductive material. The electron emission sub-layer 208 can be any metal or other non-metal material having a low work function and a high carrier concentration (e.g., magnesium, palladium, or a polymer material). Alternatively, the electron emission sub-layer 208 may be made from a monolayer.

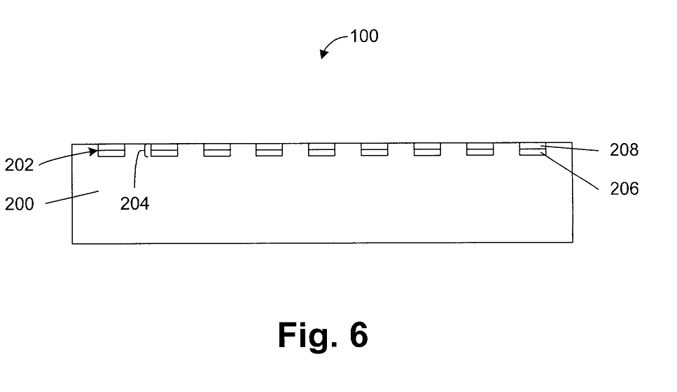

FIG. 6 is a side view of the partially completed device layer shown in FIG. 5 after patterning of the cathode electrode layer 204. The cathode electrode layer 204 is removed from those areas of the nanoimprinted substrate 200 that are outside the indentations 202. The removal of the cathode electrode layer 204 may be achieved with an argon plasma etch, chemical mechanical polishing or any other method that will remove the cathode electrode layer 204 that is outside of the indentations 202 while leaving the cathode electrode layer 204 that is inside the indentations 202.

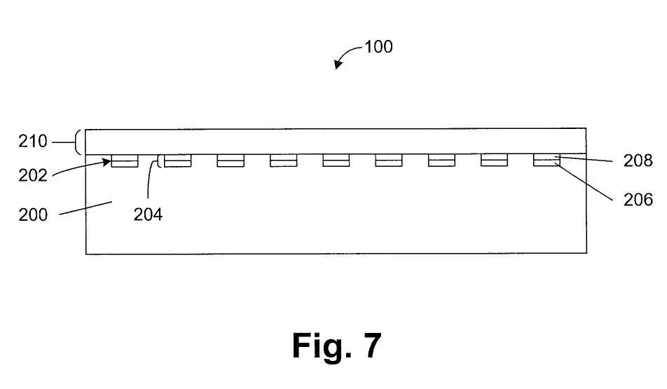

FIG. 7 is a side view of the partially completed device layer shown in FIG. 6 after deposition of the pit pillar structure layer 210. The pit pillar structure layer 210 may be made from an ultraviolet curable photopolymer or any other suitable material capable of being patterned in the sub-micron range.

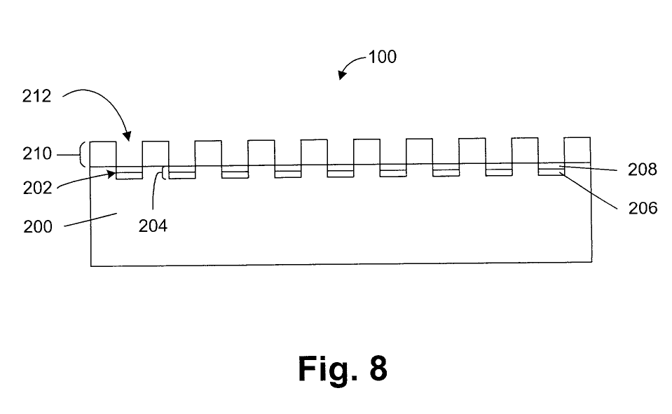

FIG. 8 is a side view of the partially completed device layer shown in FIG. 7 after a hot embossing method or another suitable method such as laser ablation is used to form pixel pits 212 in the pit pillar structure layer 210. The hot embossing method uses a stamper having a surface configured to produce the desired pattern of pixel pits 212. The pit pillar structure layer 210 is relatively thin (e.g., about 200 nm) and can be formed to have pillars with extremely small diameters (e.g., about 500 nm or less). The pit pillar structure layer 210 material remaining at the bottom of the pixel pits 212 is removed with a reactive ion etching or another suitable method. The cathode electrode layer 204 is then treated with an oxygen plasma or another suitable method to enable good contact with an n-type polymer material 214 that is to be deposited in the pixel pits 212.

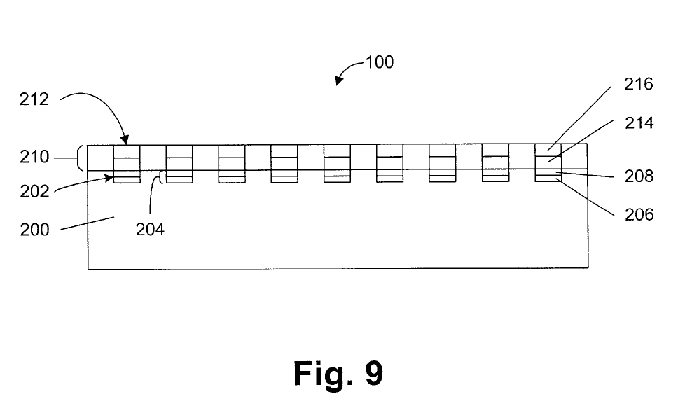

FIG. 9 is a side view of the partially completed device layer shown in FIG. 8 after deposition of the light emitting materials 214, 216. The n-type light emitting material 214 is formed by a liquid deposition method. Liquid deposition methods include pit filling methods such as molecular adhesion and electro-deposition methods such as electro-polymerized. The ability of the pit filling methods to fill the pixel pits 212 are limited by the adhesive characteristics and molecular size of the materials used. A p-type light emitting material 216 is similarly formed on top of the n-type light emitting material 214. The light emitting materials 214, 216 can be any semiconducting organic polymer material or materials that can be formed into a pn light emitting diode. The light emitting materials 214, 216 may be selected to have substantially the same thickness and have a combined thickness substantially equal to a thickness of the pit pillar structure layers 210 (e.g., each light emitting layer is 100 nm thick).

The light emitting organic polymer or polymers that form the light emitting materials 214, 216 are deposited and/or flow into the pixel pits 212 because they are in a liquid state.

The liquid light emitting materials 214, 216 are initially deposited over the surface of the device layer 100 and then flow from the higher points to the lower points. Non-liquid depositions such as vapor depositions are unable to flow and will remain where initially deposited. Thus, the flow of the liquid light emitting materials 214, 216 from the top of the pit pillar structure layer 210 (i.e., the higher points) into the pixel pits 212 (i.e., the lower points) obviates the need to etch or otherwise pattern the light emitting organic polymer materials initially deposited outside the pixel pits 212.

The light emitting materials 214, 216 are indirectly patterned by the patterning of the pit pillar structure layer 210. Specifically, the patterning of the pit pillar structure layer 210 produces a topography that directs the liquid deposited light emissive material 214, 216 into the pixel pits 212 since the pixel pits 212 happen to be the topographical low points. Thus, the pattern of the pit pillar structure layer 210 determines the pattern of the light emissive materials 214, 216 without requiring a traditional patterning of the light emissive materials 214, 216. This is important because the light emitting materials 214, 216 are poorly suited to patterning by conventional methods while the materials of the pit pillar structure layer 210 are well suited to patterning. Accordingly, the much smaller dimensional limits of the pit pillar structure layer 210 as compared to the dimensional limits of the light emitting materials 214, 216 allows for a decreased pixel size that greatly increases the density with which data may be stored.

Excess light emitting polymer material may be removed with argon plasma or another suitable plasma or with a more expensive polishing technique such as chemical mechanical polishing.

FIG. 10 is a side view of the partially completed device layer shown in FIG. 9 after formation of the anodes 218. A transparent conductor such as indium tin oxide is deposited to a thickness of about 100 nm by vacuum deposition or liquid deposition. The deposited transparent conductor is then patterned with an etching process to form the anodes 218. The addition of the anodes 218 completes the device layer 100. The device layer 100 may now be tested by conventional means to determine whether or not the device layer is defective. The non-defective device layers 100 can be individually used in devices or may be laminated with other non-defective device layers 100 to form a multi-layer laminate that can be used in devices.

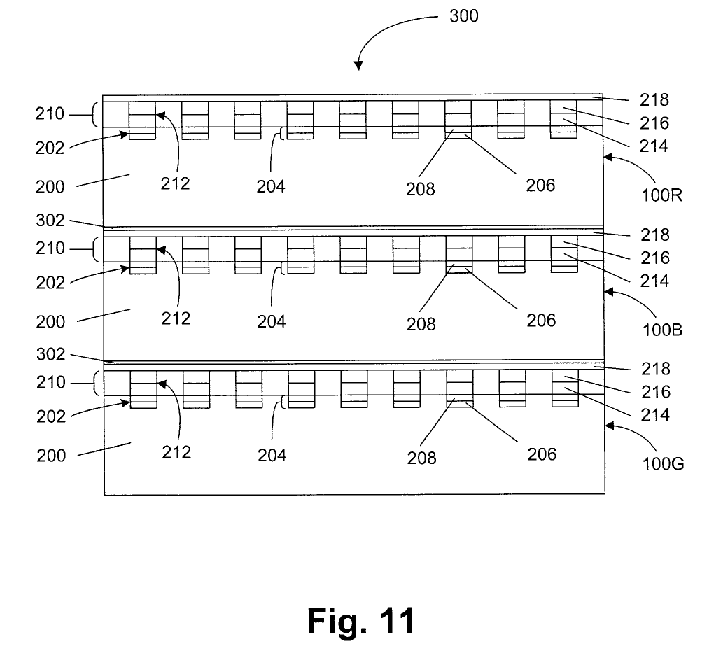

FIG. 11 is a side view of a multi-layer laminate 300 according to an exemplary embodiment of the present invention. The laminate 300 includes three completed device layers 100R, 100B, 100G. The completed device layers 100R, 100B, 100G each produce light of a different frequency. In this figure, the first completed device layer 100R produces red light, the second completed device layer 100B produces blue light and the third completed device layer 100G produces green light. In any given laminate 300, the device layers 100 may be attached to each other with an adhesive 302 such as a pressure sensitive adhesive or by thermal bonding, photopolymerization or another suitable method. A device layer 100 may be peeled from a laminate 300 if the device layer 100 is discovered to be damaged or otherwise defective. This improves the overall yield for laminate 300 production making the laminate less expensive to produce.

Additional layers and elements may also be incorporated into the present invention. For example, optical films may be included to improve the optical coupling of light between the device layers (e.g., antireflective films). Additionally, layers and elements already part of the present invention may be selected and/or formed to provide multiple functions. For example, the thickness and refractive index of an adhesive used to couple two adjacent device layers 100 could be selected to better couple light between the device layers 100.

The small pixel size of the organic light emitting devices of the present invention is well suited to optical memory. The invention may also be applied to display devices, especially color display devices and other devices having electroluminescent elements.

Although several embodiments of the present invention and its advantages have been described in detail, it should be understood that changes, substitutions, transformations, modifications, variations, permutations and alterations may be made therein without departing from the teachings of the present invention, the spirit and the scope of the invention being set forth by the appended claims.

We claim:

1. A method of making an electroluminescent element comprising:
forming a cathode;
forming a layer;
forming pixel pits in the layer;
depositing light emitting material into the pixel pits by a liquid deposition; and
forming an anode such that the anode and the cathode can excite the light emitting material.

2. The method of claim 1, wherein at least one non-thickness dimension of the pixel pit is equal to or less than about 10 μm.

3. The method of claim 1, wherein at least one non-thickness dimension of the pixel pit is equal to or less than 5 μm.

4. The method of claim 1, wherein at least one non-thickness dimension of the pixel pit is equal to or less than 1 μm.

5. The method of claim 1, wherein at least one non-thickness dimension of the pixel pit is between about 0.5 μm and about 1.0 μm.

6. The method of claim 1, wherein the electroluminescent element is part of an optical memory device.

7. The method of claim 1, wherein the electroluminescent element is part of a display device.

8. The method of claim 1, wherein the forming a cathode includes indenting a substrate.

9. The method of claim 8, wherein the indenting is a nanoimprinted lithographic indentation.

10. The method of claim 1, wherein the forming an anode includes depositing a transparent conductive material and the forming a cathode includes depositing a transparent conductive material.

11. The method of claim 1, wherein the forming a cathode includes forming an electron emission sub-layer.

12. The method of claim 1, further comprising laminating the electroluminescent element to another electroluminescent element.

13. The method of claim 1, wherein the liquid deposition is a pit filling method.

14. The method of claim 13, wherein the pit filling method is molecular adhesion.

15. The method of claim 1, wherein the liquid deposition is an electro-deposition.

16. The method of claim 15, wherein the electro-deposition is eletro-polymerization.

17. The method of claim 1, wherein the depositing light emitting material into the pixel pits includes the light emitting material flowing into the pixel pits.

18. An electroluminescent element comprising:
a layer including pixel pits;
an organic polymer light emitting pixel formed in the pixel pits, a first portion of the organic polymer light emitting pixel being an n-type material and a second portion of the organic polymer light emitting pixel being a p-type material; and
an anode and a cathode for applying an excitation to the organic polymer light emitting pixel,
wherein at least one dimension organic polymer light emitting pixel parallel to the layer is equal to or less than about 10 μm.

19. The layer of claim 18, wherein the at least one dimension is less than about 5 μm.

20. The layer of claim 18, wherein the at least one dimension is less than about 1 μm.

21. The layer of claim 18, wherein the at least one dimension is between about 0.5 μm and about 1.0 μm.

22. The layer of claim 18, wherein the element is part of an optical memory device.

23. The layer of claim 18, wherein the element is part of a display device.

24. The layer of claim 18, further wherein the cathode is formed in indentations in a substrate.

25. The layer of claim 24, wherein the indentations are nanoimprinted indentations.

26. The layer of claim 18, wherein the anode includes a transparent conductive material and the cathode includes a transparent conductive material.

27. The layer of claim 18, wherein the cathode has a transparent conductor sub-layer and an electron emission sub-layer.

28. The layer of claim 18, wherein the element is part of a laminate.

29. A method of making an optical memory element comprising:
lithographically nanoimprinting a substrate;
forming an cathode by depositing a transparent conductive material on the substrate and by depositing an electron emission material on the transparent conductive material;
forming a layer on the cathode;
forming pixel pits in the layer;
depositing light emitting material into the pixel pits by a liquid deposition; and
forming an anode by depositing a transparent conductive material such that the anode and the cathode can excite the light emitting material,
wherein at least one non-thickness dimension of the pixel pits is between about 0.5 μm and about 1.0 μm.

30. An electroluminescent optical memory element comprising:
a substrate with nanoimprinted indentations;
a layer including pixel pits;
an organic polymer light emitting pixel formed in the pixel pits, a first portion of the organic polymer light emitting pixel being an n-type material and a second portion of the organic polymer light emitting pixel being a p-type material; and
an indium tin oxide anode and a dual layer cathode for applying an excitation to the organic polymer light emitting pixel, the dual layer cathode including an indium tin oxide sub-layer and an electron emissive sub-layer having a low work function and high carrier concentration,
wherein at least one dimension organic polymer light emitting pixel parallel to the layer is between about 0.5 μm and about 1.0 μm.
